(19) United States
(12) Patent Application Publication
(10) Pub. No.: US 2015/0021568 A1
(43) Pub. Date: Jan. 22, 2015

(54) ORGANIC LIGHT EMITTING DISPLAY APPARATUS AND METHOD OF MANUFACTURING THE SAME

(71) Applicant: Samsung Display Co., Ltd., Yongin-city (KR)

(72) Inventors: Su-Cheol GONG, Yongin-city (KR); Souk-June HWANG, Yongin-city (KR)

(73) Assignee: Samsung Display Co., Ltd., Yongin-city (KR)

(21) Appl. No.: 14/184,035

(22) Filed: Feb. 19, 2014

(30) Foreign Application Priority Data
Jul. 22, 2013 (KR) 10-2013-0086258

(51) Int. Cl. H01L 51/52; H01L 51/56

(52) U.S. Cl. CPC H01L 51/5237; H01L 51/56
USPC 257/40; 438/28

(57) ABSTRACT

An organic light-emitting display apparatus including a substrate, a display unit arranged on the substrate, an encapsulation substrate arranged on the display unit, a first filler provided between the substrate and the encapsulation substrate, a second filler provided between the substrate and the encapsulation substrate and separate from the first filler, and a sealant provided between the first filler and the second filler and bonding the substrate and the encapsulation substrate.

### CROSS-REFERENCE TO RELATED APPLICATION

This application claims priority from and the benefit of Korean Patent Application No. 10-2013-0086258, filed on Jul. 22, 2013, which is hereby incorporated by reference for all purposes as if fully set forth herein.

### BACKGROUND

1. Field

Exemplary embodiments of the present invention relate to an organic light-emitting display apparatus and a method of manufacturing the same.

2. Discussion of the Background

In general, display apparatuses, such as organic light-emitting display apparatuses provided with thin film transistors (TFTs), may be utilized in mobile devices such as smartphones, tablet personal computers, super-slim laptops, digital cameras, video cameras, and personal digital assistants, or electronic products, such as thin TVs and, thus, such display apparatuses receive much attention.

A gap between upper and lower substrates of the organic light-emitting display apparatus should be sealed to protect the organic light-emitting device. To this end, a sealing member is applied between the upper and lower substrates and then hardened to thereby bond the upper and lower substrates. The lifetime and reliability of the display apparatus depends on the degree of bonding between the upper and lower substrates.

The above information disclosed in this Background section is only for enhancement of understanding of the background of the invention and, therefore, it may contain information that does not form the prior art that is already known in this country to a person of ordinary skill in the art.

### SUMMARY

Exemplary embodiments of the present invention provide an organic light-emitting display apparatus having improved bonding strength and a reduced cutting margin, and a method of manufacturing the same.

Additional aspects will be set forth in part in the description which follows and, in part will be apparent from the description, or may be learned by practice of the invention.

An exemplary embodiment of the present invention discloses an organic light-emitting display apparatus including a substrate, a display unit disposed on the substrate, an encapsulation substrate disposed on the display unit, a first filler disposed between the substrate and the encapsulation substrate, a second filler disposed between the substrate and the encapsulation substrate and separate from the first filler, and a sealant disposed between the first filler and the second filler, the sealant bonding the substrate to the encapsulation substrate.

An exemplary embodiment of the present invention also discloses a method of manufacturing an organic light-emitting display apparatus including forming a display unit on one surface of a substrate; forming a first filler on one surface of an encapsulation substrate; forming a second filler outside of the first filler on the encapsulation substrate; forming a sealant between the first filler and the second filler on the encapsulation substrate; and bonding the substrate and the encapsulation substrate with the sealant.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a plan view schematically illustrating a part of an organic light-emitting display apparatus according to an exemplary embodiment of the present invention.

FIG. 2 is a cross-sectional view schematically illustrating the organic light-emitting display apparatus of FIG. 1.

FIG. 3 is a plan view schematically illustrating a part of an organic light-emitting display apparatus according to another exemplary embodiment of the present invention.

FIG. 4 is a cross-sectional view schematically illustrating the organic light-emitting display apparatus of FIG. 3.

FIG. 5 is a cross-sectional view schematically illustrating a part of the organic light-emitting display apparatus of FIG. 1 or FIG. 3.

FIGS. 6, 7, 8, 9, and 10 are schematic cross-sectional views illustrating a method of manufacturing the organic light-emitting display apparatus, according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of elements may be exaggerated for clarity. Like reference numerals in the drawings denote like elements.

It will be understood that when an element or layer is referred to as being “on”; “connected to”; or “coupled to” another element or layer, it can be directly on; directly connected to; or directly coupled to the other element or layer, or intervening elements or layers may be present. In contrast, when an element or layer is referred to as being “directly on”; “directly connected to”; or “directly coupled to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

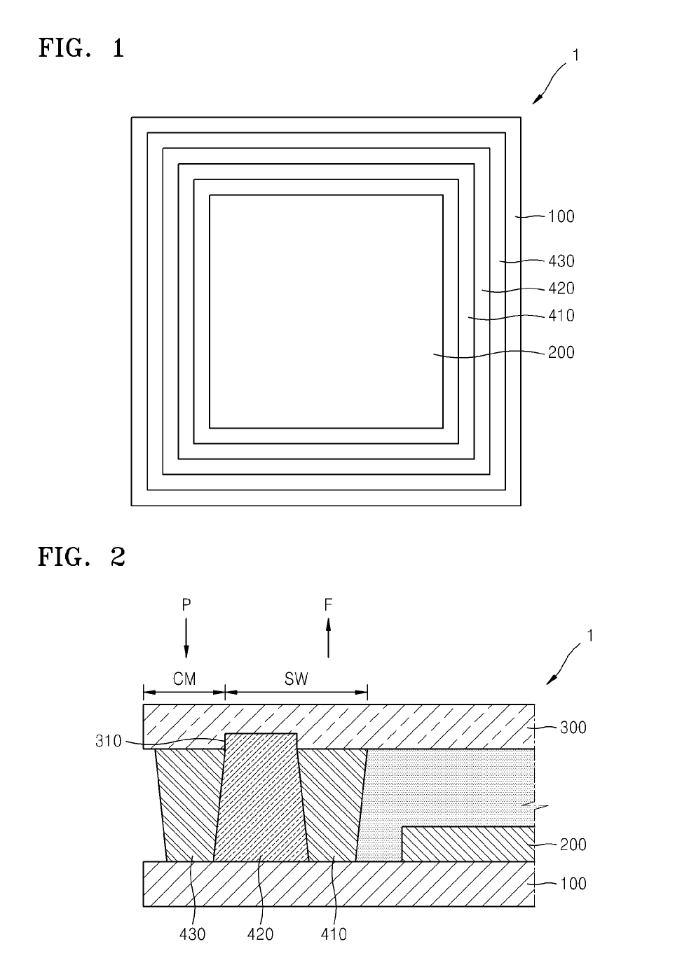

FIG. 1 is a plan view schematically illustrating a part of an organic light-emitting display apparatus 1 according to an exemplary embodiment of the present invention, and FIG. 2 is a cross-sectional view schematically illustrating the organic light-emitting display apparatus 1 of FIG. 1. For reference, an encapsulation substrate 300 illustrated in FIG. 2 is omitted in FIG. 1.

Referring to FIGS. 1 and 2, a display unit 200 provided with an organic light-emitting device is disposed on a substrate 100. The substrate 100 may include transparent glass primarily composed of SiO₂. The substrate 100 is not limited thereto, and may also be formed of transparent plastic.

In the case of a bottom emission type in which an image is displayed in the direction of the substrate 100, the substrate 100 may be formed of a transparent material. However, in the case of a top emission type in which an image is displayed away from the substrate 100, the substrate 100 does not have to be formed of a transparent material.

Although not illustrated in the drawings, a buffer layer may be further disposed on an upper surface of the substrate 100 to planarize the substrate 100 and block impurities.

The substrate 100 provided with the display unit 200 is bonded to the encapsulation substrate 300 disposed on the display unit 200. A glass material and also a plastic material, such as an acrylic, may be used for the encapsulation substrate 300. A groove 310 may be formed in a surface of the encapsulation substrate 300 contacting a sealant 420.

The substrate 100 and the encapsulation substrate 300 are bonded by the sealant 420 and a second filler 430. A first filler 410, the sealant 420, and the second filler 430 may be disposed on the upper surface of the substrate 100.

The first filler 410 is provided between the substrate 100 and the encapsulation substrate 300 and bonds the substrate 100 to the encapsulation substrate 300. The first filler 410 may include a thermosetting organic polymer material. The first filler 410 may include an epoxy resin, a silicone-based resin, an acrylic-based resin, a polyimide-based resin, a urethane-based resin, or a cellulose-based resin. The first filler 410 blocks impurities, and improves bonding strength between the substrate 100 and the encapsulation substrate 300 with a greater adhesive strength than that of the sealant 420. Because the first filler 410 has a higher shock absorption coefficient than that of the sealant 420, the first filler 410 may protect a panel from an inner or outer shock, thereby improving the mechanical strength of the organic light-emitting display apparatus 1.

The second filler 430 is provided between the substrate 100 and the encapsulation substrate 300, and may be separate from the first filler 410. The second filler 430 may include a thermosetting organic polymer material. The second filler 430 may include an epoxy resin, a silicone-based resin, an acrylic-based resin, a polyimide-based resin, a urethane-based resin, or a cellulose-based resin. The second filler 430 blocks impurities, and improves bonding strength between the substrate 100 and the encapsulation substrate 300 with a higher adhesive strength than that of the sealant 420. The encapsulation substrate 300 may be cut at a position flush with the second filler 430. Because the second filler 430 fills a space between the substrate 100 and the encapsulation substrate 300, a lifting force F of the encapsulation substrate 300, generated by the pressing pressure P of a cutting wheel, may be reduced. Therefore, when the encapsulation substrate 300 and the substrate 100 are cut, a substantial cutting margin CM may be minimized. Thus, a non-display region of the organic light-emitting display apparatus 1 may be reduced in size, and an outward appearance of the organic light-emitting display apparatus 1 may also be improved.

The sealant 420 is provided between the first filler 410 and the second filler 430, and bonds the substrate 100 and the encapsulation substrate 300. The sealant 420 may include frit. The frit may be formed of a glass material, such as P₂O₅, V₂O₅, Bi₂O₃, B₂O₃, ZnO, SnO, or a mixture of at least two thereof. Here, transition elements may be further added to the frit, and/or a ceramic filler for adjusting CTE may be further added to the frit. The sealant 420 may serve as a main blocking layer for preventing an organic material of the display unit 200 from being deformed by impurities, such as external oxygen and moisture.

The groove 310 may be formed in a surface of the encapsulation substrate 300 contacting a sealant 420. The groove 310 is formed by etching or processing the encapsulation substrate 300, and the sealant 420 is printed in the groove 310, so that the sealant 420 fits into the groove 310 of the encapsulation substrate 300. Because the groove 310 is formed in a surface of the encapsulation substrate 300 which contacts a sealant 420, a bonding surface area between the encapsulation substrate 300 and the sealant 420 may increase. Thus, the bonding strength between the encapsulation substrate 300 and the substrate 100 may increase, and the mechanical strength of the organic light-emitting display apparatus 1 may also increase.

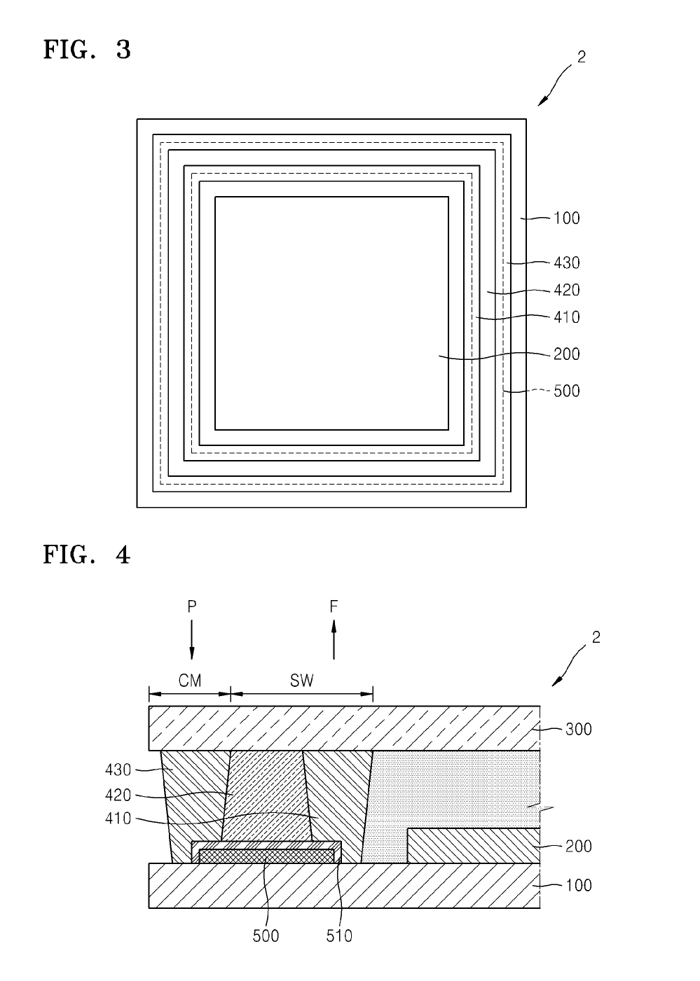

FIG. 3 is a planar view schematically illustrating a part of an organic light-emitting display apparatus 2 according to another exemplary embodiment of the present invention, and FIG. 4 is a cross-sectional view schematically illustrating the organic light-emitting display apparatus 2 of FIG. 3. For reference, an encapsulation substrate 300 illustrated in FIG. 4 is omitted in FIG. 3.

Hereinafter, the present exemplary embodiment will be described by focusing on its differences from the exemplary embodiment of FIG. 1. Referring to FIGS. 3 and 4, a display unit 200 provided with an organic light-emitting device is disposed on a substrate 100. The substrate 100 and the encapsulation substrate 300 are bonded by a first filler 410, a sealant 420, and a second filler 430.

A circuit unit 500 may be arranged under the first filler 410, the sealant 420, or the second filler 430. The circuit unit 500 may be arranged outside the display unit 200 and may input signals to a thin film transistor of the display unit 200. The circuit unit 500 may be provided with a plurality of thin film transistors. A protective layer 510 may be provided on the thin film transistors to protect the thin film transistors and planarize upper portions thereof. Because the first filler 410, the sealant 420, and/or the second filler 430 is formed on the circuit unit 500, a non-display region of the organic light-emitting display apparatus 2 may be reduced in size, and an outward appearance of the organic light-emitting display apparatus 2 may also be improved.

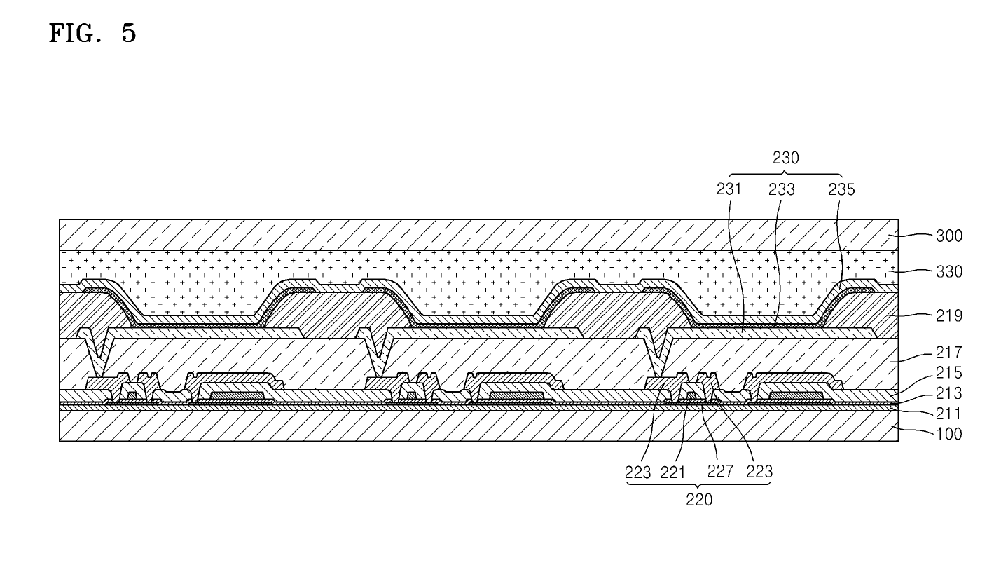

FIG. 5 is a cross-sectional view schematically illustrating a part of the organic light-emitting display apparatus 1 of FIG. 1 or the organic light-emitting display apparatus of FIG. 3. FIG. 5 illustrates an exemplary structure of the display unit 200.

Referring to FIG. 5, thin film transistors 220 are disposed on the substrate 100, and an organic light-emitting device 230 is provided on each of the thin film transistors 220. The organic light-emitting device 230 includes a pixel electrode 231 electrically connected to the thin film transistor 220, an opposite electrode 235 arranged over the substrate 100, and an intermediate layer 233 arranged between the pixel electrode 231 and the opposite electrode 235 and including at least an emission layer.

The thin film transistor 220, including a gate electrode 221, source and drain electrodes 223, a semiconductor layer 227, a gate insulating layer 213, and an interlayer insulating layer 215, is disposed on the substrate 100. The thin film transistor 220 is not limited to the type illustrated in FIG. 5. Various thin film transistors, such as an organic thin film transistor in which the semiconductor layer 227 is formed of an organic material, or a silicon thin film transistor in which the semiconductor layer 227 is formed of silicon, may be used. A buffer layer 211 formed of silicon oxide or silicon nitride may be provided, as necessary, between the thin film transistor 220 and the substrate 100.

The semiconductor layer 227 may be formed of polycrystalline silicon. However, the semiconductor layer 227 is not limited thereto, and may alternatively be formed of an oxide semiconductor. For example, the oxide semiconductor may include an oxide of a material selected from Group 12, 13, and 14 metal elements, such as zinc (Zn), indium (In), gallium (Ga), tin (Sn), cadmium (Cd), germanium (Ge), and hafnium (Hf), or a combination thereof. For example, the oxide semiconductor layer 227 may include G-I-Z-O[(In₂O₃)a(Ga₂O₃)b(ZnO)c] (a, b, and c are real numbers satisfying a≧0, b≧0, c>0).

The organic light-emitting device 230 includes the pixel electrode 231 facing the opposite electrode 235 with the intermediate layer 233 disposed therebetween. The intermediate layer 233, which includes at least an emission layer, may be provided with a plurality of layers, as described later.

The pixel electrode 231 may act as an anode electrode, and the opposite electrode 235 may act as a cathode electrode, but these polarities may be reversed.

The pixel electrode 231 may include a transparent electrode or a reflective electrode. When the pixel electrode 231 includes a transparent electrode, the pixel electrode 231 may be formed of ITO, IZO, ZnO, or In₂O₃. When the pixel electrode 231 includes a reflective electrode, the pixel electrode 231 may include a reflective layer formed of Ag, Mg, Al, Pt, Pd, Au, Ni, Nd, Ir, Cr, or a compound thereof, and a layer formed of ITO, IZO, ZnO, or In₂O₃ on the reflective layer.

The opposite electrode 235 may include a transparent electrode or a reflective electrode. When the opposite electrode 235 includes a transparent electrode, the opposite electrode 235 may include both a layer in which Li, Ca, LiF/Ca, LiF/Al, Al, Mg, or a compound thereof is deposited so as to face the intermediate layer 233 and an auxiliary electrode or a bus electrode line formed of a transparent electrode-forming material, such as ITO, IZO, ZnO, or In₂O3. When the opposite electrode 235 includes a reflective layer, the opposite electrode 235 may be formed by depositing Li, Ca, LiF/Ca, LiF/Al, Al, Mg, or a compound thereof.

A pixel-defining layer (PDL) 219 is disposed to cover an edge of the pixel electrode 231, and has a thickness that increases toward the outside of the pixel electrode 231. The pixel-defining layer 219 defines an emission region and increases a gap between the edge of the pixel electrode 231 and the opposite electrode 235 to prevent electric fields from being concentrated on the edge portion of the pixel electrode 231, thereby preventing a short circuit between the pixel electrode 231 and the opposite electrode 235.

Various types of the intermediate layer 233, including at least an emission layer, may be provided between the pixel electrode 231 and the opposite electrode 235. The intermediate layer 233 may be formed of a low molecular organic material or a polymeric organic material. The intermediate layer 233 may constitute one unit pixel with sub pixels for emitting red, green, and blue lights.

When using a low molecular organic material, one or a combination of a hole injection layer (HIL), a hole transport layer (HTL), an organic emission layer (EML), an electron transport layer, and an electron injection layer (EIL) may be stacked to form the intermediate layer 233. Copper phthalocyanine (CuPc), N,N′-Di(naphthalene-1-yl)-N,N′-diphenyl-benzidine (NPB), tris-8-hydroxyquinoline aluminum (Alq3), or the like may be used as the low molecular organic material. Vapor deposition may be performed with these low molecular organic materials using a mask.

When using a polymeric organic material, the intermediate layer 233 may have an HTL and an EML. PEDOT may be used as the HTL, and a polymeric organic material, such as a polyphenylene vinylene or polyfluorene-based material, may be used as the EML.

A lower part of the organic light-emitting device 230 is electrically connected to the thin film transistor 220. If a planarizing layer 217 for covering the thin film transistor 220 is provided, the organic light-emitting device 230 is disposed on the planarizing layer 217, and the pixel electrode 231 of the organic light-emitting device 230 is electrically connected to the thin film transistor 220 through a contact hole in the planarizing layer 217.

In the above-mentioned exemplary embodiments, the intermediate layer 233 is formed in an opening so that each pixel has a light-emitting material. However, the present invention is not limited thereto. The intermediate layer 233 may be formed to be common to all pixels regardless of positions of the pixels. In this case, for example, the intermediate layer 233 may be formed by vertically stacking or combining layers including light-emitting materials emitting red, green, and blue light. Another color may also be combined if a white color is to be emitted. Furthermore, a color conversion layer for converting the emitted white color into another color, or a color filter may be provided.

The organic light-emitting device 230 formed on the substrate 100 is sealed by the encapsulation substrate 300. As described above, the encapsulation substrate 300 may be formed of various materials, such as glass or a plastic material.

A filler 330 is provided between the organic light-emitting device 230 and the encapsulation substrate 300 to fill a gap between the organic light-emitting device 230 and the encapsulation substrate 300, thereby preventing exfoliation or cell breakage.

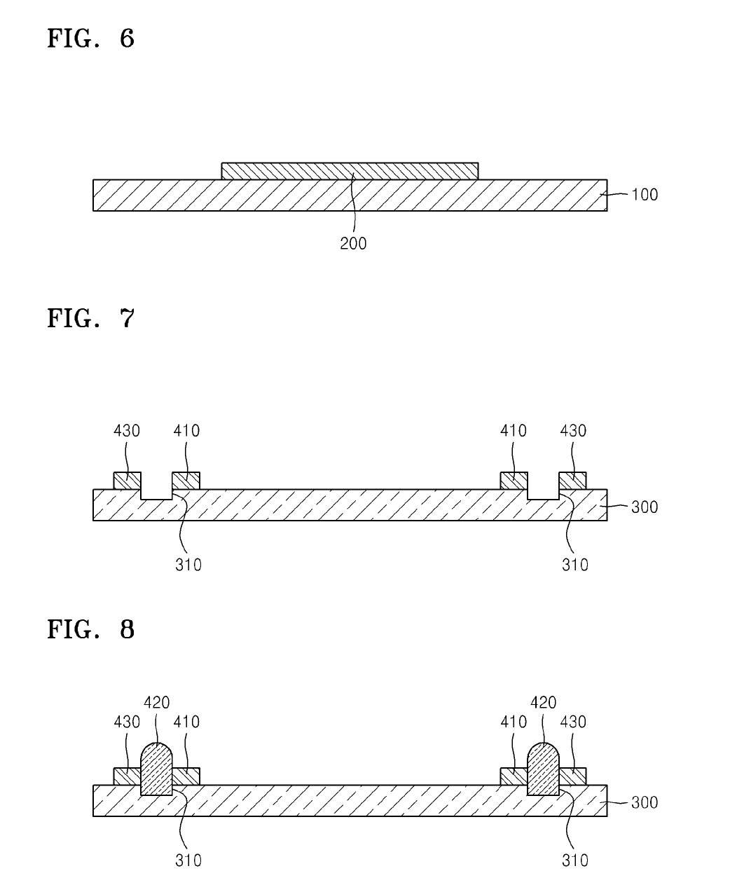

FIGS. 6 to 10 are schematic cross-sectional views illustrating a method of manufacturing the organic light-emitting display apparatus.

As illustrated in FIG. 6, a display unit 200 is formed on one surface of a substrate 100. A glass material or a plastic material, such as acryl, may be used for the substrate 100. A buffer layer (not illustrated) may be further provided, as necessary, to the substrate 100.

As illustrated in FIG. 7, an encapsulation substrate 300 is prepared. A glass material or a plastic material, such as acryl, may be used for the encapsulation substrate 300. A groove 310 may be formed in the encapsulation substrate 300 by etching or processing the encapsulation substrate 300.

A first filler 410 and a second filler 430 are formed on one surface of the encapsulation substrate 300. The second filler 430 is formed at the outside of the first filler 410. The first filler 410 and the second filler 430 may include a thermosetting organic polymer material and may include an epoxy resin, a silicone-based resin, an acryl-based resin, a polyimide-based resin, a urethane-based resin, and a cellulose-based resin. The first filler 410 and the second filler 430 may be formed by screen printing. When the first filler 410 and the second filler 430 are formed of the same material, the first filler 410 and the second filler 430 may be simultaneously formed by screen printing. When the groove 310 is formed in the encapsulation substrate 300, the first filler 410 and the second filler 430 may be formed such that the groove 310 is disposed therebetween. After printing the first filler 410 and the second filler 430, the first filler 410 and the second filler 430 are dried and hardened.

As illustrated in FIG. 8, a sealant 420 is formed between the first filler 410 and the second filler 430 on the encapsulation substrate 300. When the groove 310 is formed between the first filler 410 and the second filler 430, the sealant 420 may be formed on the groove 310. Because the groove 310 is formed in a surface of the encapsulation substrate 300 which contacts the sealant 420, a bonding surface area between the encapsulation substrate 300 and the sealant 420 may increase, and thus the bonding strength between the encapsulation substrate 300 and the substrate 100 may increase. Therefore, the mechanical strength of the organic light-emitting display apparatus may increase. The sealant 420 may include frit. The sealant 420 may be formed by screen printing. After printing the sealant 420, the sealant 420 is dried.

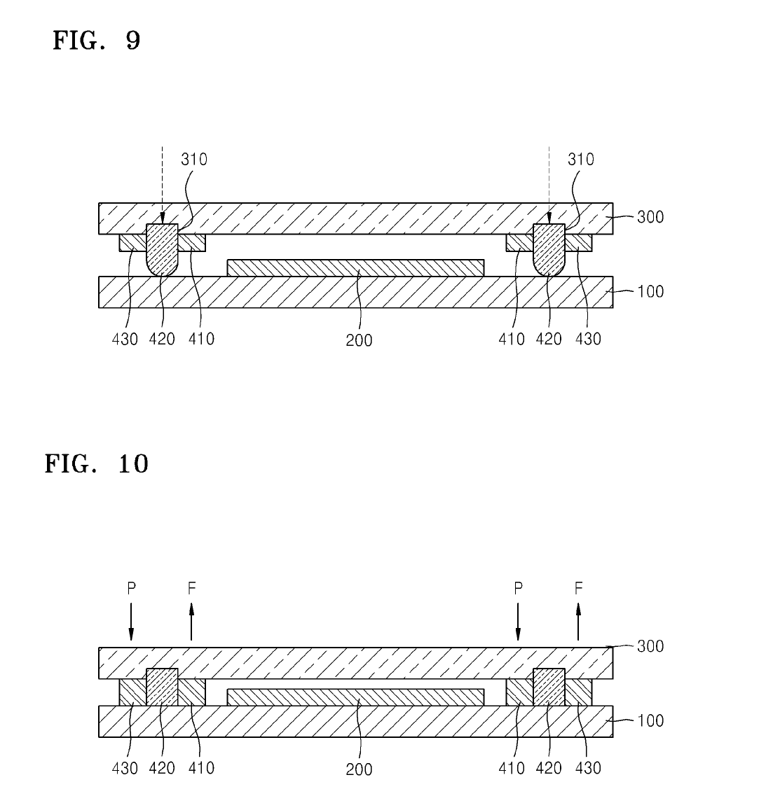

As illustrated in FIG. 9, the substrate 100 and the encapsulation substrate 300 are bonded through the sealant 420. The first filler 410, the sealant 420, or the second filler 430 may be disposed on the upper surface of the substrate 100. The sealant 420 is fired by partially irradiated with laser radiation or by using a jig for applying heat, so as to bond the substrate 100 and the encapsulation substrate 300. The first filler 410 and the second filler 430 include a thermosetting agent, and may be sufficiently hardened by heat transferred from the sealant 420.

The sealant 420 may be formed of glass frit powder, an organic binder, and an organic solvent. A process of vaporizing and removing the organic solvent is referred to as “drying”, a temperature at which the organic binder included in frit is decomposed is referred to as a “curing temperature”, and a temperature at which the frit is softened or melted is referred to as a “bonding temperature”. Therefore, the first filler 410 and the second filler 430, which may be used as reinforcing agents, may harden at a temperature equal to or lower than a decomposing temperature of the organic binder, i.e. the curing temperature of the frit, and may be deformed or thermally broken at a temperature higher than the bonding temperature of the frit. Because the bonding temperature (softening temperature or melting temperature) of the frit is about 350-400° C., and the bonding temperature has been decreased to about 220-300° C., the drying and hardening temperature of the first and second fillers 410 and 430 may be about 150-300° C., and the deformation and thermal breakage temperature of the first and second fillers 410 and 430 may be about 200-400° C. or higher.

The substrate 100 and the encapsulation substrate 300 may be aligned and bonded so that the first filler 410, the sealant 420, or the second filler 430 is disposed on a circuit unit 500 on the substrate 100. Because the first filler 410, the sealant 420, or the second filler 430 is formed on the circuit unit 500, the size of a non-display region of the organic light-emitting display apparatus may be reduced, thereby improving the outward appearance of the organic light-emitting display apparatus. As illustrated in FIG. 10, the organic light-emitting display apparatus may be manufactured as the sealant 420 is hardened.

The encapsulation substrate 300 may be cut at a position flush with the second filler 430. Because the second filler 430 fills a space between the substrate 100 and the encapsulation substrate 300, a lifting force F of the encapsulation substrate 300, generated as a result of the pressing pressure P of a cutting wheel, may be reduced. Therefore, when the encapsulation substrate 300 and the substrate 100 are cut, a substantial cutting margin may be minimized, and thus a non-display region of the organic light-emitting display apparatus may be reduced, and an outward appearance of the organic light-emitting display apparatus may also be improved.

As discussed above, FIGS. 6-10 show that the upper and lower substrates are bonded after forming the first filler 410, the sealant 420, and the second filler 430 on the encapsulation substrate 300. However, alternatively, the sealant 420 may be printed and dried on the encapsulation substrate 300, the first and second fillers 410 and 430 may be printed and dried on the substrate 100, and then the upper and lower substrates may be aligned and the sealant 420 may be fired, thereby bonding the substrates.

As described above, according to the exemplary embodiments of the present invention, the lifespan and reliability of the organic light-emitting display apparatus may be improved by improving the bonding strength between upper and lower substrates.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An organic light-emitting display apparatus, comprising:
a substrate;
a display unit disposed on the substrate;
an encapsulation substrate disposed on the display unit;
a first filler disposed between the substrate and the encapsulation substrate;
a second filler disposed between the substrate and the encapsulation substrate and separate from the first filler; and
a sealant disposed between the first filler and the second filler, the sealant bonding the substrate to the encapsulation substrate.

2. The organic light-emitting display apparatus of claim 1, wherein a groove is formed on a surface of the encapsulation substrate that contacts the sealant.

3. The organic light emitting-display apparatus of claim 1, further comprising a circuit unit arranged under at least one of the first filler, the sealant, and the second filler.

4. The organic light-emitting display apparatus of claim 3, further comprising a protective layer covering the circuit unit.

5. The organic light-emitting display apparatus of claim 1, wherein the sealant comprises frit.

6. The organic light emitting-display apparatus of claim 1, wherein the first filler and the second filler comprise a thermosetting organic polymer material.

7. The organic light emitting-display apparatus of claim 1, wherein a curing temperature of the sealant is higher than hardening temperatures of the first filler and the second filler, and is lower than thermal breakage temperatures of the first filler and the second filler.

8. The organic light emitting-display apparatus of claim 7, wherein the hardening temperatures of the first filler and the second filler are in a range of about 150° C. and about 300° C.

9. The organic light emitting-display apparatus of claim 7, wherein the thermal breakage temperatures of the first filler and the second filler are in a range of about 200° C. and about 400° C.

10. A method of manufacturing an organic light-emitting display apparatus, comprising:
forming a display unit on a substrate;
forming a first filler on an encapsulation substrate;
forming a second filler outside of the first filler on the encapsulation substrate;
forming a sealant between the first filler and the second filler on the encapsulation substrate; and
bonding the substrate to the encapsulation substrate with the sealant.

11. The method of claim 10, wherein at least one of the first filler, the second filler, and the sealant is formed by screen printing.

12. The method of claim 10, wherein the bonding of the substrate and the encapsulation substrate comprises curing the sealant using a laser or heat.

13. The method of claim 12, wherein:
a curing temperature of the sealant is higher than hardening temperatures of the first filler and the second filler; and
the curing temperature is lower than thermal breakage temperatures of the first filler and the second filler.

14. The method of claim 13, wherein the hardening temperatures of the first filler and the second filler are in a range of about 150° C. and about 300° C.

15. The method of claim 13, wherein the thermal breakage temperatures of the first filler and the second filler are in a range of about 200° C. and about 400° C.

16. The method of claim 10, wherein the bonding of the substrate and the encapsulation substrate comprises arranging at least one of the first filler, the sealant, and the second filler on a circuit unit on the substrate.

17. The method of claim 10, wherein a groove is formed in a surface of the encapsulation substrate that contacts the sealant.

18. The method of claim 10, further comprising cutting the encapsulation substrate at a position flush with the second filler.

19. The method of claim 10, wherein the sealant comprises frit.

20. The method of claim 10, wherein the first filler and the second filler comprise a thermosetting organic polymer material.
